(19) United States
(12) Patent Application Publication
(10) Pub. No.: US 2008/0242113 A1
(43) Pub. Date: Oct. 2, 2008

(54) FILM FORMING METHOD OF HIGH-K DIELECTRIC FILM

(75) Inventors: Shintaro AOYAMA, Nirasaki-shi (JP); Tsuyoshi TAKAHASHI, Nirasaki-shi (JP); Kouji SHIMOMURA, Nirasaki-shi (JP); Miki ARUGA, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/101,514

(22) Filed: Apr. 11, 2008

Related U.S. Application Data
(63) Continuation of application No. PCT/JP2006/318864, filed on Sep. 22, 2006.

(30) Foreign Application Priority Data
Oct. 12, 2005 (JP) 2005-298158

(51) Int. Cl. H01L 21/31

(52) U.S. Cl. 438/781; 257/E21.24

(57) ABSTRACT

A method for forming a high-K dielectric film on a silicon substrate includes the steps of processing a surface of the silicon substrate with a diluted hydrofluoric acid, conducting nucleation process of HfN, after the step of processing with the diluted hydrofluoric acid, by supplying a metal organic source containing Hf and nitrogen to the surface of said silicon substrate, and forming an Hf silicate film by a CVD process, after the step of nucleation, by supplying a metal organic source containing Hf and a metal organic source containing Si to the surface of the silicon substrate.

### CROSS-REFERENCE TO RELATED APPLICATIONS

The present invention is a continuation application filed under 35 U.S.C.111(a) claiming benefit under 35 U.S.C.120 and 365(c) of PCT application JP2006/318864 filed on Sep. 22, 2006 and Japanese Patent Application 2005-298158 filed on Oct. 12, 2005, the entire contents of each are incorporated herein as reference.

### BACKGROUND OF THE INVENTION

The present invention generally relates to film formation technologies and more particularly to a method for forming a metal silicate film and a fabrication process of a semiconductor device that uses a metal silicate film.

With advancement of miniaturization technologies, it is now possible to fabricate ultra miniature and ultra fast-speed semiconductor devices having a gate length of 0.1 μm or less.

With such ultra miniature and ultra fast-speed semiconductor devices, there is a need of decreasing the thickness of the gate oxide film used therein with decrease of the gate length according to scaling law. Thus, in the semiconductor devices having a gate length of 0.1 μm or less, there is a need of setting the thickness of the gate oxide film to 1-2 nm or less in the case a conventional thermal oxide film is used for the gate oxide film. However, with use of such a thin gate insulation film, there occurs increase of tunneling current, and it is not possible to avoid the problem of increase of gate leakage current.

Under these circumstances, there have been made proposals to apply so-called high-K dielectrics such as Ta₂O₅, Al₂O₃, ZrO₂, HfO₂, ZrSiO₄, HfSiO₄, or the like, for the gate insulation film in view of the fact that the high-K dielectrics have a specific dielectric constant much larger than that of a thermal oxide film and that an equivalent SiO₂ film thickness (EOT) thereof is much smaller in spite of the fact that the physical film thickness thereof is large. By using such high-K dielectrics, it becomes possible to use a gate insulation film of the physical thickness of several nanometers also in the ultra-fast semiconductor devices having a very short gate length of 0.1 μm or less, and it becomes possible to suppress the gate leakage current caused by the tunneling effect. Generally, such high-K dielectrics take a polycrystalline structure when formed on a surface of a silicon substrate.

In the case a high-K dielectric film is formed directly on a surface of a silicon substrate, there tends to be caused extensive mutual diffusion of Si atoms and metal atoms between the silicon substrate and the high-K dielectric film. Thus, it is generally practiced in the art to form such a high-K dielectric film on a surface of a silicon substrate via a very thin interface oxide film.

Meanwhile, there are proposals in these days to form a high-K dielectric film directly on a surface of a silicon substrate by choosing the source of the high-K dielectric film.

### Patent Reference 1

WO03/049173 Official Gazette

### Non-Patent Reference 1

IEICE Technical Report SDM 2002-189 (2002-10)

### SUMMARY OF THE INVENTION

It is a general object of the present invention to provide a novel and useful manufacturing method of a high-K dielectric film wherein the foregoing problems are eliminated.

Another and more specific object of the present invention is to provide a method for forming a high-K dielectric film on a silicon substrate wherein it is possible to improve interface characteristics to the silicon substrate and at the same time it is possible to improve leakage current characteristics.

In a first aspect, there is provided a method for forming a high-K dielectric film on a silicon substrate, including the steps of: processing a surface of the silicon substrate with a diluted hydrofluoric acid; conducting nucleation process of HfN, after the step of processing with the diluted hydrofluoric acid, by supplying a metal organic source containing Hf and nitrogen to the surface of the silicon substrate; and forming an Hf silicate film by a CVD process, after the step of nucleation, by supplying a metal organic source containing Hf and a metal organic source containing Si to the surface of the silicon substrate.

In another aspect, there is provided a computer-readable recording medium recorded with a program, the program causing a general purpose computer to control a substrate processing apparatus such that the substrate processing apparatus carries out a film formation process of a high-K dielectric film on a silicon substrate, the film formation process of the high-K dielectric film including the steps of: processing a surface of the silicon substrate with a diluted hydrofluoric acid; conducting nucleation process of HfN, after the step of processing with the diluted hydrofluoric acid, by supplying a metal organic source containing Hf and nitrogen to the surface of the silicon substrate; and forming an Hf silicate film by a CVD process, after the step of nucleation, by supplying a metal organic source containing Hf and a metal organic source containing Si to the surface of the silicon substrate.

According to the present invention, there is caused deposition of nitrogen atoms on the surface of the silicon substrate in the initial phase of film formation with a surface density of generally 1/100 of a surface density of Si atoms on a Si (100) surface, by supplying a metal organic source containing Hf and nitrogen to the surface of the silicon substrate after processing with diluted hydrofluoric acid. It is believed that the interface characteristics between the silicon substrate and the HfSiO₄ film are stabilized as a result of such nitrogen atoms eliminate the defects on the surface of the silicon substrate. Further, by carrying out the nucleation step of HfN at the temperature of 400° C. or less, in which there occurs no SiC formation on the surface of the silicon substrate, it becomes possible to stabilize the interface between the silicon substrate and the HfSiO₄ film further. Thus, by forming an HfSiO₄ film on the surface of a silicon substrate where nucleation of HfN has been made already, by a CVD process that uses HTB and TEOS for the source materials, it becomes possible to form an HfSiO₄ gate insulation film having stabilized threshold characteristics and reduced leakage current.

### BRIEF DESCRIPTION OF THE DRAWINGS

FIGS. 1A-1C are diagrams showing the formation process of an HfSiO₄ film on a silicon substrate according to a related art of the present invention;

FIGS. 2A-2B are diagrams showing the formation process of an HfSiO₄ film on a silicon substrate according to another related art of the present invention;

FIG. 3 is a diagram showing the construction of a film forming apparatus used with the present invention;

FIG. 4 is a diagram explaining the principle of the present invention;

FIG. 5 is a further diagram explaining the principle of the present invention;

FIG. 6 is a further diagram explaining the principle of the present invention;

FIG. 7 is a diagram showing SiC formation on a silicon substrate surface;

FIG. 8 is a further diagram explaining the principle of the present invention;

FIG. 9 is a flowchart showing a substrate processing method according to a first embodiment of the present invention;

FIGS. 10A-10C are diagrams showing the substrate processing step corresponding to FIG. 9;

FIG. 11 is a diagram showing another substrate processing apparatus used with the first embodiment of the present invention;

FIG. 12 is a flowchart showing a substrate processing method according to a second embodiment of the present invention;

FIG. 13 is a diagram showing a film structure formed with the second embodiment of the present invention;

FIG. 14 is a diagram showing the construction of a cluster-type substrate processing apparatus according to a third embodiment of the present invention;

FIG. 15 is a flowchart showing the substrate processing carried out with the cluster-type substrate processing apparatus of FIG. 14;

FIGS. 16A and 16B are diagrams showing the microwave plasma processing apparatus used with the cluster-type substrate processing apparatus of FIG. 14; and

FIG. 17 is a diagram showing the construction of a general purpose computer constituting a control unit in the cluster-type substrate processing apparatus of FIG. 14.

### DETAILED DESCRIPTION OF THE PREFERRED EMBODIMENTS

### [Principle]

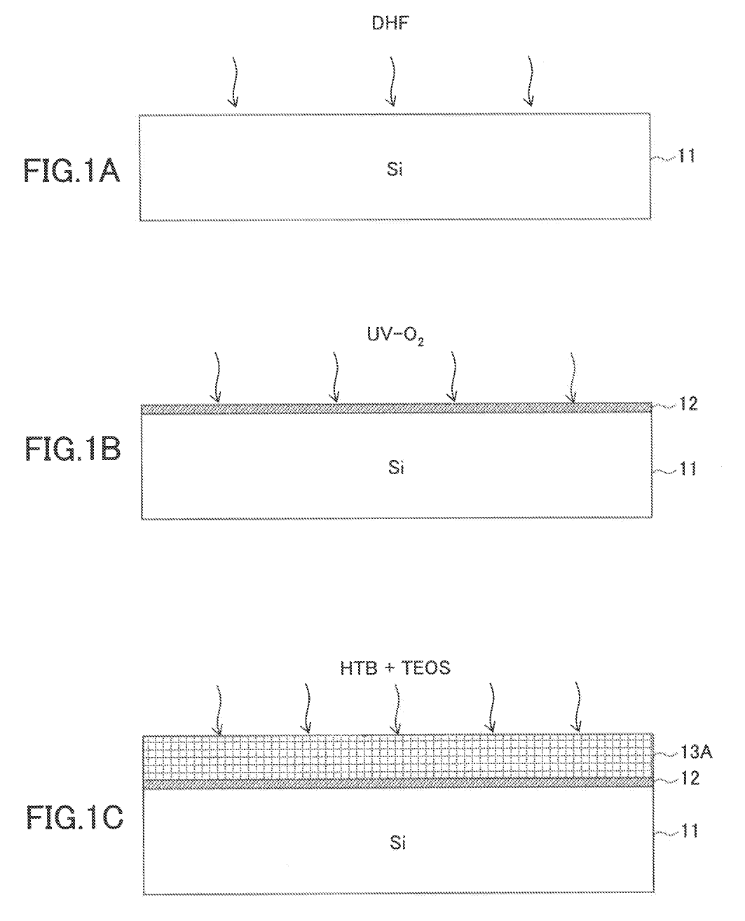

FIG. 1A-1C show the process according to a related art of the present invention for forming an HfSiO₄ film on a silicon substrate 11 via an interface oxide film.

Referring to FIG. 1A, there is applied a diluted fluoric acid (DHF) treatment to the surface of a silicon substrate 11 and removal of a native oxide film is made therefrom. At the same time, the fresh silicon surface thus exposed is terminated with hydrogen.

Next, in the step FIG. 1B, a silicon oxide film 12 is formed on the surface of the silicon substrate 11 thus processed with the DHF treatment by conducting a radical oxidation process typically at 400-500° C. while using ultraviolet-excited radicals. The silicon oxide film 12 is formed as the interface oxide film with a thickness of about 0.4 nm. Further, in the step of FIG. 1C, there is formed an HfSiO₄ film 13A on the interface oxide film typically at a substrate temperature of 480° C. by a CVD process that uses tertiary-butoxy hafnium (HTB) and tetraethoxysilane (TEOS) as the source materials.

The HfSiO₄ film 13A thus formed has a feature of small leakage current, which is advantageous for the gate insulation film of ultra fast-speed semiconductor devices.

However, it was discovered, when a field effect transistor is fabricated actually by using the HfSiO₄ film formed by using such HTB and TEOS as the source materials for the gate insulation film, that there is caused significant fluctuation of threshold voltage during the operation of such a field effect transistor. This suggests that there exist defects in the vicinity of the interface between the interface oxide film 12 and the HfSiO₄ film 13A and carriers are trapped by such defects at the time of operation of the semiconductor device.

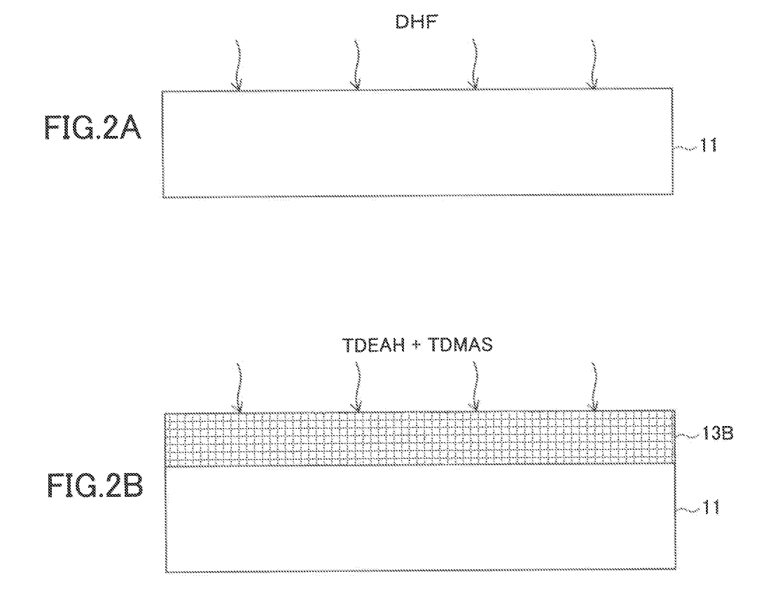

On the other hand, FIGS. 2A and 2B show the process of forming an HfSiO₄ film 13B directly on the silicon substrate 11 by a CVD process according to another related art, in which TDEAH (tetrakis diethylamido hafnium) and TDMAS (trisdimethylamido silane) are used for the source materials.

Referring to FIG. 2A, the surface of the silicon substrate 11 is processed by the DHF treatment similarly to the step of FIG. 1A for removal of native oxide film. After removal of the native oxide film, the step of FIG. 2B is conducted in which there is formed an HfSiO₄ film 13B on the silicon substrate 11 with a film thickness of several nanometers by conducting a CVD process typically at the substrate temperature of 610° C. while using TDEAH and TDMAS for the source materials. Here, it should be noted that the film formation of the HfSiO₄ film that uses TDEAH and TDMAS noted before causes a problem of increase of surface roughness at the surface of the HfSiO₄ film thus formed when the film formation process is conducted on the interface oxide film 12 as shown in FIG. 1C. Thus, the film formation of the HfSiO₄ film shown in FIG. 2A is conducted directly upon the silicon substrate 11.

While the HfSiO₄ film 13B thus formed from the source materials of TDEAH and TDMAS has the problem of large leakage current, the field effect transistor fabricated actually by using such an HfSiO₄ film for the gate insulation film shows the feature of stabilized threshold voltage. This suggests that there is formed an insulation film of excellent film quality with reduced amount of defects in the vicinity of the interface between the silicon substrate 11 and the HfSiO₄ film 13B. However, the HfSiO₄ film 13B thus formed from the source materials of TDEAH and TDMAS suffers from the problem of poor leakage current characteristics as mentioned before.

In the investigation that constitutes the foundation of the present invention, the inventor of the present invention has investigated the state of the interface between the silicon substrate 12 and the HfSiO₄ film 13B in relation to the problem which is caused in the film formation process of the HfSiO₄ film of FIGS. 2A and 2B, and has discovered a phenomenon, which eventually lead to the solution of the problem.

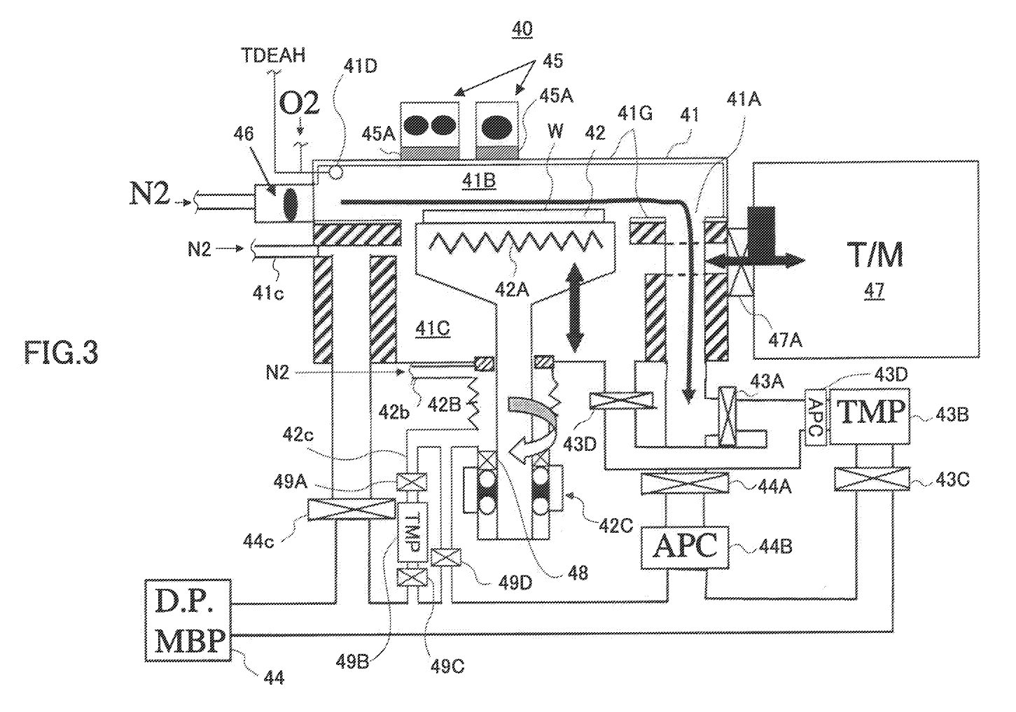

FIG. 3 shows a schematic construction of a substrate processing apparatus 40 used by the inventor of the present invention in the investigation noted above.

Referring to FIG. 3, the substrate processing apparatus 40 is an apparatus designed for forming an extremely thin silicon oxide film on a silicon substrate with a film thickness of several Angstroms by using ultraviolet-excited oxygen radicals and further nitriding the extremely thin silicon substrate with nitrogen radicals formed by a remote plasma source (reference should be made to U.S. Pat. No. 6,927,112). There, the experiments have been made by applying a partial modification to the construction of the foregoing conventional substrate processing apparatus.

Referring to FIG. 3, the substrate processing apparatus 40 includes a processing vessel 41 accommodating therein a stage 42, wherein the stage 42 includes a heater 42A and provided in a manner movable up and down between a processing position and substrate load/unload position. There, the processing vessel 41 defines a processing space 41B therein together with the stage 42. The stage 42 is rotated by a driving mechanism 42C.

The inner wall surface of the processing vessel 41 is covered with an inner liner 41G of a quartz glass and with this, metal contamination of the substrate under processing from the exposed metal surface is suppressed to the level of 1×10¹⁰ atoms/cm² or less.

Further, there is formed a magnetic seal 48 at the coupling part of the stage 42 and the driving mechanism 42C, wherein the magnetic seal 48 separates a magnetic seal chamber 42B held in a vacuum environment and the drive mechanism 42C held in the atmospheric environment. Because the magnetic seal 48 is a liquid, the stage 42 is held in the manner to rotate freely.

In the illustrated state, the stage 42 is in the processing position, and thus, there is formed a load/unload chamber 41C underneath the stage 42 for the purpose of loading and unloading of the substrate to be processed. The processing vessel 41 is coupled to a substrate transfer unit 47 via a gate valve 47A, and a substrate W to be processed is transferred from the substrate transfer unit 47 to the stage 42 via the gate valve 47A in the state that the stage 42 is lowered to the loading/unloading position 41C. Further, the substrate W after the processing is transferred from the stage 42 to the substrate transfer unit 47 in this state.

In the substrate processing apparatus 40 of FIG. 3, there is formed an evacuation port 41A on the processing vessel 41 in the part near the gate valve 47A, and the evacuation port 41A is connected to a turbo molecular pump 43B via a valve 43A and an APC (automatic pressure controller) 44B. Further, a pump 44 having a construction of coupling a dry pump and a mechanical booster pump is coupled to the turbo molecular pump 43B via a valve 43C. With this, it becomes possible to lower the pressure of the processing space 41B to 1.33×10⁻¹-1.33×10⁻⁴ Pa (10⁻³-10⁻⁶ Torr) by driving the turbo molecular pump 43B and the dry pump 44.

On the other hand, the evacuation port 41A is connected also directly to the pump 44 via a valve 44A and an APC 44B, and thus, it becomes possible to lower the pressure of the processing space to the pressure of 1.33 Pa-1.33 kPa (0.01-10 Torr) by the pump 44 by opening the valve 44A.

To the processing vessel 41, there is provided a processing gas supply nozzle 41D at the side opposite to the evacuation port 41A across the substrate W to be processed for supplying an oxygen gas and TDEAH from respective lines, wherein the gas of oxygen or TDEAH supplied to the processing gas supply nozzle 41D is caused to flow through the processing space 41B along the surface of the substrate W to be processed and evacuated from the evacuation port 41A.

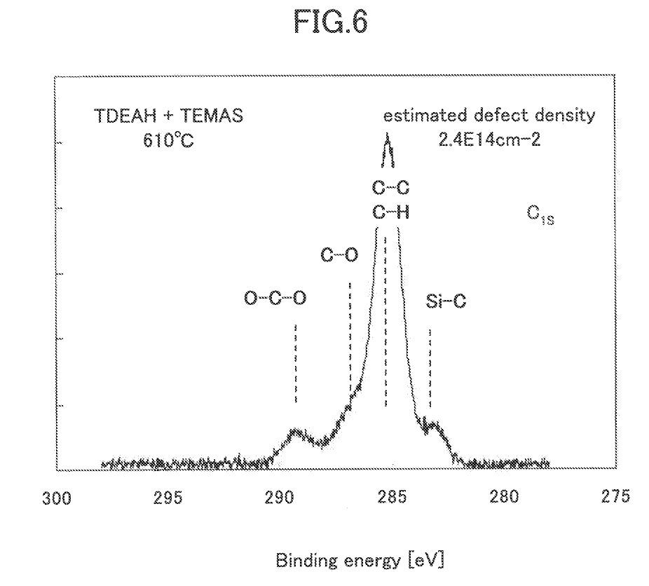

In order to activate the processing gas, particularly the oxygen gas thus supplied from the processing gas supply nozzle 41D and for forming oxygen radicals, the substrate processing apparatus 40 of FIG. 6 is provided with an ultraviolet source 45 having a quartz window 45A on the processing vessel 41 in correspondence to the region between the processing gas supply nozzle 41D and the substrate W to be processed. In the present experiment, the ultraviolet source 45 is not used. Further, the processing vessel 41 is provided with a remote plasma source 46 at the side opposite to the evacuation port 41A across the substrate W to be processed. In the present experiment, however, remote plasma source 46 is not used.

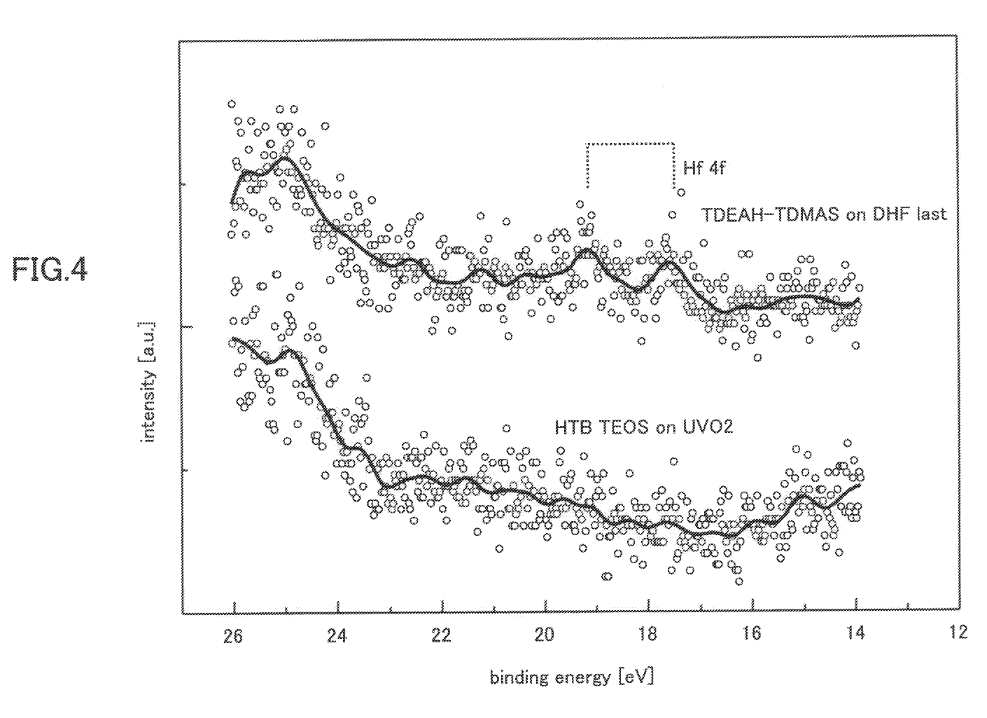

With the substrate processing apparatus 40 of FIG. 4, there is further provided a purge line 41c for purging the load/unload chamber 41C with a nitrogen gas, and there are further provided a purge line 42b and an evacuation line 42c thereof for purging the magnetic seal chamber 42B with a nitrogen gas.

In more detail, the evacuation line is coupled to a turbo molecular pump 49B via a valve 49A, and the turbo molecular pump 49B is coupled to the pump 44 via a valve 49C. Further, the evacuation line 42c is coupled directly to the pump 44 also via a valve 49D, and thus, it becomes possible to hold the magnetic seal chamber 42B at various pressures.

The load/unload chamber 41C is evacuated by the pump 44 through the valve 44C or evacuated by the turbo molecular pump 43B via the valve 43D. In order to avoid contamination in the processing space 41B, the load/unload chamber 41C is maintained at a lower pressure level than the processing space 41B, and the magnetic seal chamber 42B is maintained at a further lower pressure to the load/unload chamber 41C as a result of differential evacuation.

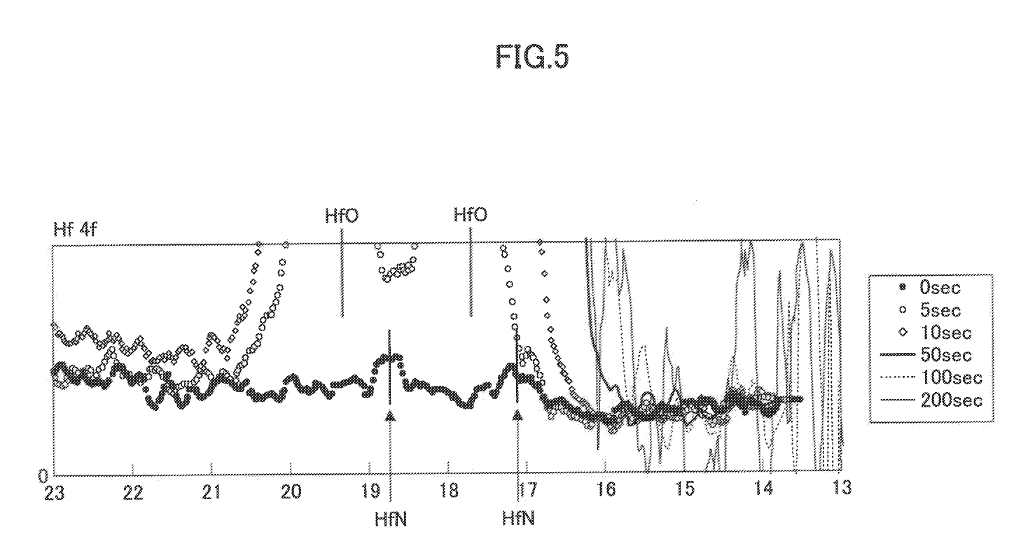

FIG. 4 shows an XPS background spectrum of the silicon substrate surface for the case in which an HfSiO₄ film is formed in the substrate processing apparatus 40 of FIG. 3 by introducing TDEAH and TDMAS, removing the silicon substrate from the processing vessel 41, purging the interior of the processing vessel with an Ar gas, introducing a new silicon substrate processed with DHF and exposed the new silicon substrate to the TDEAH ambient remaining in the processing vessel 41 after the purging step (“TDEAH-TDMAS on DHF last”). Thus, the specimen indicated as “TDEAH-TDMAS on DHF last” in FIG. 5 is in the state substantially identical with the case of exposing a silicon substrate processed with DHF to a TDEAH ambient without carrying out film formation of an HfSiO₄ film. Further, the continuous line in FIG. 5 represents the curve fitted to the measured points of XPS by means of high-speed Fourier transform (FFT).

Referring to FIG. 4, there was detected a peak of Hf4d orbital in the XPS measurement, and with this, it was confirmed that there is caused deposition of Hf on the silicon substrate surface. It is believed that such Hf is originated from the TDEAH remaining in the processing vessel.

On the other hand, the specimen indicated in FIG. 4 as “HTB TEOS on UVO₂” indicates the XPS background spectrum for the case of: forming an HfSiO₄ film on a silicon substrate on which an oxide film is formed with a thickness of several Angstroms according to the steps of FIG. 1A-1C by way of ultraviolet-excited oxygen radicals; taking out the silicon substrate form the processing vessel 41 of the substrate processing apparatus 40; purging the interior of the processing vessel 41 with an Ar gas; introducing a new silicon substrate into the processing vessel; and exposing the new silicon substrate to the ambient of HTB and TEOS remaining therein.

Referring to FIG. 4, it can be seen that there is detected no Hf peak at all with the specimen of “HTB TEOS on UVO₂”. This result is different from the previous specimen of “TDEAH-TDMAS on DHF last”.

FIG. 5 is a diagram showing the vicinity of the peak for the Hf₄d orbital in the XPS spectrum of FIG. 4. In FIG. 5, it should be noted that there are shown spectra for the case the film formation is continues for various durations, in overlapping to the XPS spectrum of FIG. 5 (film formation duration is 0 seconds).

Referring to FIG. 5, it can be seen that the XPS peak of Hf4d orbital shows a chemical shift caused by HfN, while this indicates that there is caused substantial formation of HfN already on the surface of the silicon substrate 12 by the residual ambient before starting substantial growth of the HfSiO₄ film. Further, it was confirmed that HfN remains on the silicon substrate even when the HfSiO₄ film is grown on the silicon substrate surface by supplying TDEAH and TDMAS in correspondence to the step of FIG. 2B, as can be seen from the XPS spectra for the cases in which the film formation duration is changed to 5 seconds, 10 seconds, 50 seconds, 100 seconds and 200 seconds.

On the other hand, in the state of FIG. 4, and hence in the state before starting the substantial film formation of the HfSiO₄ film, no XPS peak of HfO was observed, indicating that there is formed no HfO₂ on the surface of the silicon substrate 12.

From the XPS peak of FIG. 5, it is estimated that the surface density of nitrogen atoms on the surface of the silicon substrate 12 is 8.4×10¹² cm⁻², while it should be noted that this value corresponds to about 1/100 of the value of the surface density of Si (7×10¹⁴ cm⁻²) on the silicon (100) surface. Thus, it is believed that the nitrogen atoms deposited on the silicon substrate surface in the state bonded with Hf cause preferential bonding with defects that are distributed sparsely on the silicon substrate surface, and with this, the defects that act as the trap of electrons or holes are eliminated. Thereby, shift of threshold voltage is suppressed in the case field effect transistors are fabricated.

With the process of FIGS. 1A-1C, on the other hand, there occurs no bonding of nitrogen atoms with the defects on the silicon substrate surface, and such an interface acting as the trap of carriers remains at the interface between the silicon substrate 11 and the silicon oxide film even after formation of the HfSiO₄ film 13A.

Further, the inventor of the present invention has investigated the reason why an HfSiO₄ film of excellent leakage current characteristics is obtained with the steps of FIGS. 1A-1C while the steps of FIGS. 2A and 2B can provide only an HfSiO₄ film of poor leakage characteristics.

FIG. 6 shows an XPS spectrum of C1s orbital at the foregoing silicon substrate for the case of: conducting the steps of FIGS. 2A and 2B; purging the interior of the processing vessel with an Ar gas; introducing a new silicon substrate; and holding at 610° C. (0 seconds for film formation).

Referring to FIG. 6, there are observed peaks corresponding to an O—C—O bond, a C—O bond, a C—C bond and a C—H bond in the XPS spectrum, while this indicates that there is caused deposition of carbon atoms on the foregoing silicon substrate, wherein the carbon atoms are believed to be originated from metal organic compounds or organic silicon compounds contained in the residual ambient.

On the other hand, it is observed, in the XPS spectrum of FIG. 6, that there is caused a chemical shift associated with a Si—C bond. This suggests that the carbon atoms deposited on the silicon substrate form SiC by bonding to the Si atoms.

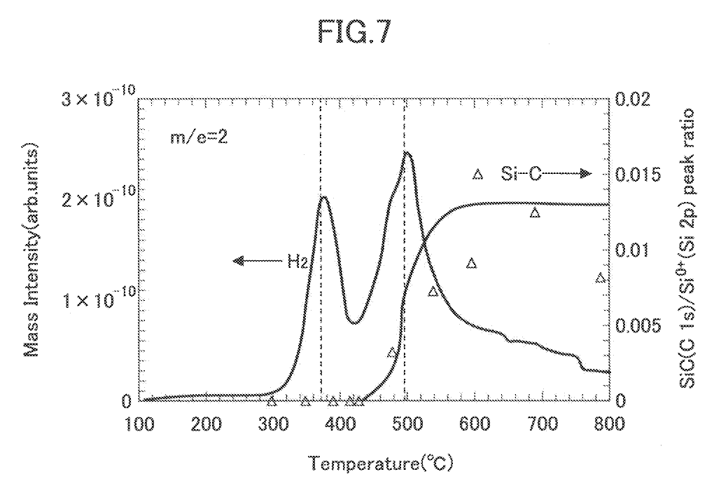

FIG. 7 is a diagram showing a model of SiC formation on the silicon substrate surface as reported in Non-Patent Reference 1.

Referring to FIG. 7, the hydrogen atoms terminating the silicon substrate surface are decoupled in the form of SiH₂ or SiH when the silicon substrate has been heated to about 400° C., resulting in exposure of active silicon surface. Substantially at the same time to the decoupling of the hydrogen atoms, there is started formation of SiC on the foregoing surface of the silicon substrate by carbon of the ambient, wherein the formation of SiC starts sharply at the substrate temperature of about 450° C. and the SiC formation reaction proceeds drastically when the substrate temperature has exceeded 500° C. SiC thus formed on the silicon substrate surface form defects. For example, it is known that the SiC thus formed causes deterioration of leakage current characteristics of the silicon oxide film formed on the silicon substrate surface.

The fact that SiC is detected in the XPS spectrum of FIG. 6 suggests that the SiC thus formed on the silicon substrate surface according to the mechanism of FIG. 7 may be the cause of deterioration of the leakage current characteristics of the HfSiO₄ film. Judging from the height of the SiC peak, the surface density of the carbon atoms on the Si substrate surface is calculated to be 2.4×10¹⁴ cm⁻², while this value corresponds to the state in which one of three silicon atoms on the silicon substrate surface is bonded to a single carbon atom.

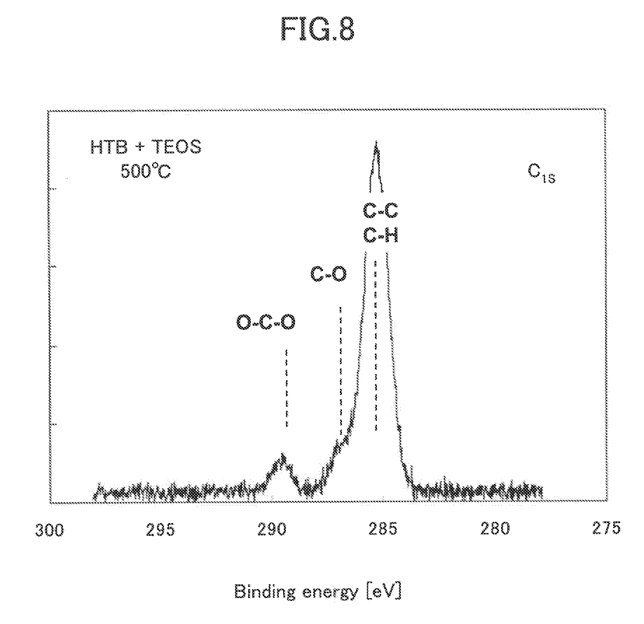

On the other hand, FIG. 8 shows a C1s XPS spectrum for the case of: conducting the steps of FIGS. 1A-1C; purging the interior of the processing vessel; introducing a new silicon substrate; conducting ultraviolet radical oxidation processing; and holding at 500° C.

Referring to FIG. 8, there exists an oxide film on the silicon substrate surface, and this is the reason that there occurs no SiC formation.

With the steps of FIG. 1A-1C, there is formed an ultraviolet-radical oxide film 12 on the silicon substrate 11 at the low temperature of about 400° in the initial phase of FIG. 1B, and thus, there is caused no SiC formation on the silicon substrate surface. It is believed that, because of this, there is caused no deterioration of leakage current caused by SiC defects even when the HfSiO₄ film is deposited in the step (C) of FIG. 1.

Thus, the present invention proposes formation of an HfSiO₄ film having excellent leakage current characteristics by first carrying out the nucleation process of HfN, and thus exposing the silicon substrate to TDEAH or an amide-based metal organic source of Hf, such that defects on the silicon substrate surface are eliminated by using nitrogen atoms, and then carrying out a CVD process that uses HTB and TEOS for the source materials. Thereby, by carrying out the nucleation process at the temperature of 400° C. or lower, it becomes possible to suppress formation of SiC on the silicon substrate surface, and it becomes possible to form a high-quality HfSiO₄ film by carrying out a film formation process thereafter at a higher temperature of about 600° C. while using HBT and TEOS for the source materials.

### First Embodiment

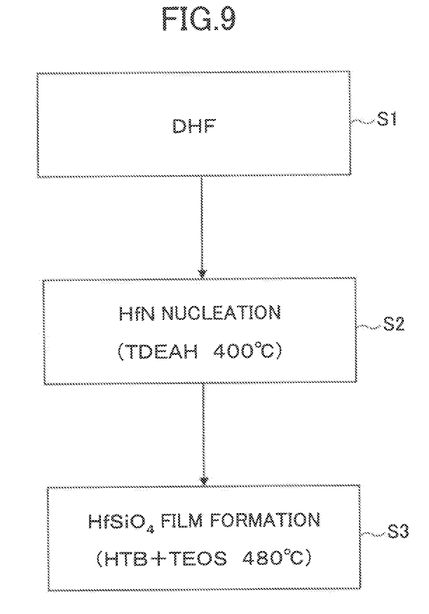

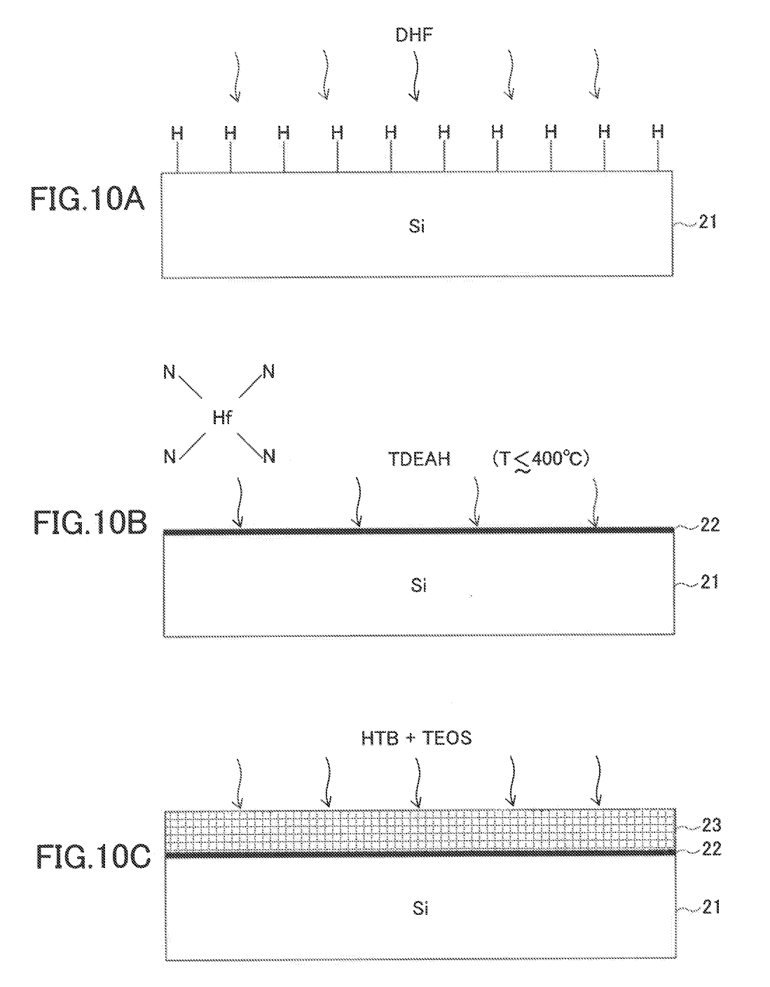

FIG. 9 is a flowchart for forming an HfSiO₄ film according to a first embodiment of the present invention, while FIGS. 10A-10C are diagrams showing the process of substrate processing corresponding to the flowchart of FIG. 9.

Referring to FIG. 9, the silicon substrate 21 is subjected to a DHF processing in the step 1 as shown in FIG. 10A. With this, native oxide film is removed and the silicon substrate surface is terminated with hydrogen.

Next, in the step 2 of FIG. 9, TDEAH is supplied to the surface of the silicon substrate 21 thus processed with DHF as shown in FIG. 10B, and there is formed an HfN layer 22 as a nucleation layer at the temperature of 400° C. or lower.

Further, in the step of FIG. 10C, an HfSiO₄ film 23 is formed on the silicon substrate 21 formed with the HfN nucleation layer 22 with a desired thickness such as 2-4 nm, for example, while using HTB and TEOS for the source materials.

With the present embodiment, the sides on the surface of the silicon substrate 21 that can form a trap of carriers are eliminated as a result of bonding with the nitrogen atoms by first forming the HfN nucleation layer 22 processed with DHF, and the electric characteristics of the interface between the silicon substrate 21 and the HfSiO₄ film 23 are stabilized.

Further, by carrying out the formation of the HfN nucleation layer 22 at the temperature of 400° C. or lower, in which there occurs no growth of SiC defects on the silicon substrate surface, it becomes possible to avoid formation of defects in the HfSiO₄ film formed in the step of FIG. 10C. Further, there is formed no SiC defects on the surface of the silicon substrate 21 even when the step of FIG. 10C is conducted at a high temperature of 600° C. or higher because the surface of the silicon substrate 21 is already covered with the HfN nucleation layer 22. Thus, there is caused no SiC formation on the surface of the silicon substrate 21, and the HfSiO₄ film shows excellent leakage current characteristics.

For example, in the case of carrying out the step of FIG. 10A with the substrate processing apparatus 40 of FIG. 3, the silicon substrate 21 processed with DHF of FIG. 10A is held on the stage 21 in the processing vessel as the substrate W to be processed and held at a substrate temperature of 400° C. Further, the internal pressure of the processing vessel 41 is set to 200 Pa, and TDEAH alone is supplied from the processing gas supply nozzle 41D with a flow rate of 0.2 SCCM, for example. By holding this state for 10-20 seconds, the HfN nucleation layer 22 is formed on the surface of the silicon substrate 21 in correspondence to the step of FIG. 10B with a surface density of the nitrogen atoms of at least 8.4×10¹²/cm².

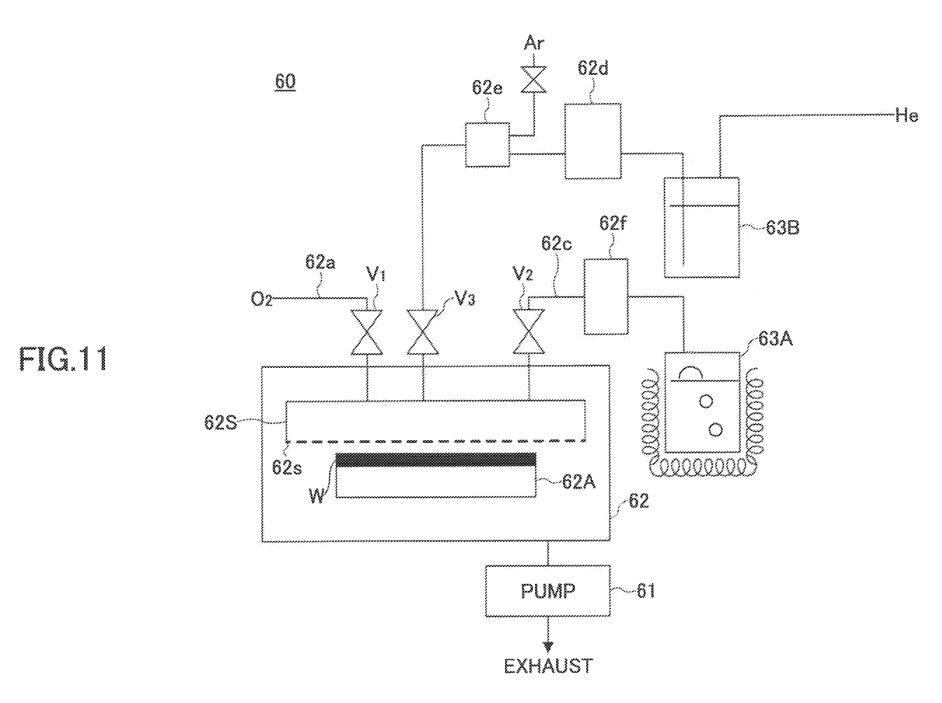

Further, with the present embodiment, the step of FIG. 10C is carried out by an MOCVD apparatus 60 shown in FIG. 11.

Referring to FIG. 11, the MOCVD apparatus 60 is provided with a processing vessel 62 evacuated by a pump 61 and a stage 62A for holding a substrate W to be processed is provided inside the processing vessel 62.

Further, there is provides a showerhead 62S in the processing vessel 62 so as to face the substrate W to be processed, and a line 62a supplying an oxygen gas is supplied to the showerhead 62S via an MFC (mass flow controller) not illustrated and a valve V1.

The MOCVD apparatus 60 is provided with a vessel 63B for holding a metal organic compound source material such as tertiary butyl hafnium (HTB), or the like, wherein the metal organic compound source material in the vessel 63 is supplied to a vaporizer 62e by a pumping gas such as a He gas via a liquid mass flow controller 62d, and a metal organic compound source gas vaporized in the vaporizer 62e as a result of assist with a carrier gas of Ar, or the like, is supplied to the showerhead 62S via the valve V3.

Further, the MOCVD apparatus 60 is provided with a heated vessel 63A for holding an organic silicon compound source such as TEOS and an organic silicon compound source gas vaporized in the heated vessel 63A is supplied to the showerhead 62S via an MFC 62b and a valve V2.

In the showerhead 62S, the oxygen gas, the organic silicon compound source gas and the metal organic compound source gas are passed through respective paths and are released to a processing space inside the processing vessel 62 from apertures 62s that are formed on the showerhead 62S at the side facing the silicon substrate W.

Thus, with the present embodiment, the silicon substrate 21 of the state FIG. 10B is introduced into the processing vessel 62 and is held on the stage 62A as a substrate w to be processed. Further, the internal pressure of the processing vessel 62 is set to 40 Pa and the substrate temperature is set to 480° C., and HTB and TEOS are introduced from the showerhead 62S with respective flow rates of 0.2 SCCM and 0.2 SCCM. With this, an HfSiO₄ film is formed on the silicon substrate 21, on which the HfN nucleation layer 22 is formed, with a film thickness of 2-4 nm.

While the present embodiment has been explained for the example of using TDEAH as the organic amide compound of Hf, the present invention is not limited to such a specific compound and it is also possible to use other organic amido compounds such as TEMAH (tetrakis ethylmethylamido hafnium), TDMAH (tetrakis dimethylamido hafnium), or the like.

Further, while the example of using HTB for the metal organic source of Hf and TEOS for the organic Si source in the step 3 of FIG. 9 in the present embodiment, the present invention is not limited to such specific compounds, it is also possible to use other organic Hf source such as TDEAH or other organic silicon compound such as TDMAS.

Further, the CVD step of FIG. 10C can be carried out at the temperature of 400° C. or higher as shown in FIG. 2. Particularly, it is possible to form a high quality HfSiO₄ film at the temperature exceeding 600° C. such as 610° C.

Further, while the step 2 of FIG. 9, and thus the step FIG. 10B is carried out with the substrate processing apparatus 40 of FIG. 3, and the step 3, and hence the step of FIG. 10C is carried out with the substrate processing apparatus 60 of FIG. 11 with the present embodiment, it is also possible to carry out the both steps with the substrate processing apparatus 60 of FIG. 11.

### Second Embodiment

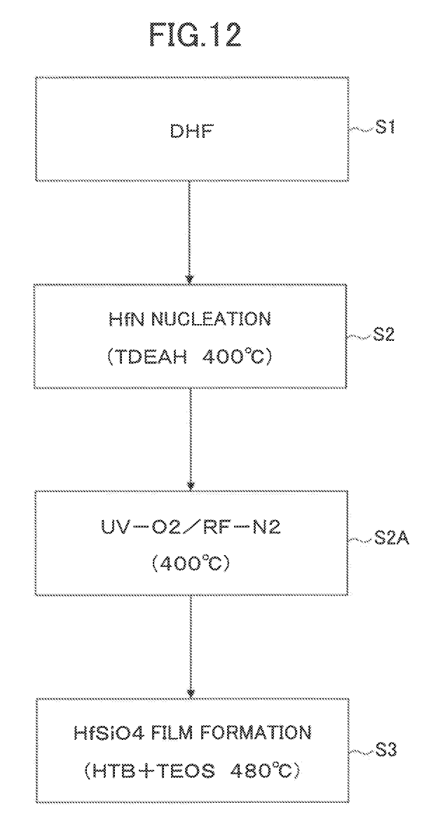

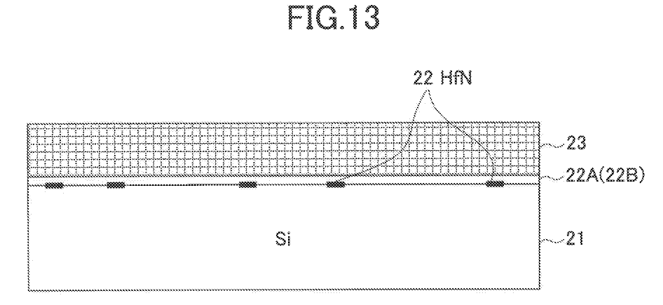

FIG. 12 is a flowchart showing the film forming process of an HfSiO₄ film according to a second embodiment of the present invention, while FIG. 13 shows the structure formed with the present embodiment. In FIGS. 12 and 13, those steps corresponding to the steps explained before are designated by the same reference numerals and the description thereof will be omitted.

Referring to FIG. 12, the present embodiment forms a silicon oxide film 22A of the film thickness of about 0.4 nm on the silicon substrate surface at the temperature of 400° C., in which there occurs no formation of SiC, by driving, after forming the HfN nucleation layer 22 on the silicon substrate 21 in the step 2, the ultraviolet source 45 of the substrate processing apparatus 40 of FIG. 4 and further introducing the oxygen gas into the processing space 41B from the processing gas supply nozzle 41D in the step 2A (FIG. 13).

The silicon oxide film thus formed covers a part of the silicon substrate 21 not covered with HfN and thus prevents the formation of SiC on the silicon substrate surface positively in the later step of FIG. 3 in which the HfSiO₄ film 23 is deposited at a high temperature. Such ultraviolet radical oxidation processing can be carried out under the processing pressure of 2.66 Pa, for example, while supplying an oxygen gas with the flow rate of 200 SCCM and driving the ultraviolet source 45 of a Xe excimer lamp.

Further, with the step 2A of FIG. 12, it is further possible to excite the nitrogen gas by RF, after the ultraviolet excited radial oxidation processing, by using the remote plasma source 46, wherein the nitrogen radicals thus formed are used to nitride the silicon oxide film 22A on the surface of the substrate. With such a nitriding processing, the silicon oxide film 22A is converted to an oxynitride film 22B at least at the surface thereof, and as a result, there occurs increase of the K value of the film and improvement of the leak current characteristics. With regard to the ultraviolet-excited radical oxidation processing and the RF radical nitridation processing in the step 2A of FIG. 12, reference should be made to Patent Reference 1.

As a result of the step 2A, the surface of the silicon substrate 21 is covered continuously by the silicon oxide film 22A or the silicon oxynitride film 23A, and thus, there occurs no formation of SiC defects even when the HfSiO₄ film 23 is formed in the step 3 of FIG. 2 at the temperature of 600° C., for example. Thereby, it is possible to improve the leakage current characteristics of the HfSiO₄ film 23 significantly.

With the present embodiment, there is formed an HfN nucleation layer 22 underneath the silicon oxide film 22A or the silicon oxynitride film 22B as shown in FIG. 13 and the defects on the silicon substrate surface that becomes trap of carriers are eliminated. Thus, with the ultra fast semiconductor devices that use such a structure for the gate insulation film, there arises no shift in the threshold voltage.

With the present embodiment, it is not necessary that the HfN nucleation layer formed in the step 2 of FIG. 12 covers the surface of the silicon substrate 21 continuously but it is sufficient that the HfN nucleation layer 22 causes a bond with the sites that form a defect on the silicon substrate surface. Thus, it is sufficient to carry out the nucleation process for a very short time (about 10 seconds).

### Third Embodiment

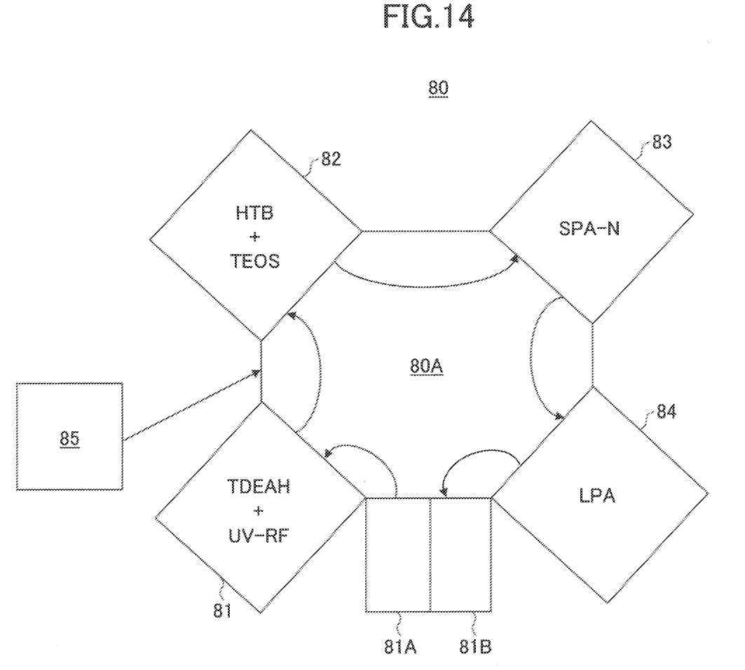

FIG. 14 shows the construction of a cluster-type substrate processing apparatus 80 according to a third embodiment of the present invention.

Referring to FIG. 14, the substrate processing apparatus 80 includes a vacuum substrate transfer chamber 80A coupled with load-lock chambers 81A and 81B, wherein the vacuum transfer chamber 80A is coupled with a processing chamber 81 of the substrate processing apparatus 40, a processing chamber 82 of the substrate processing apparatus 60, a processing chamber 83 of a microwave plasma nitridation apparatus, and a processing chamber 84 of a low-pressure annealing apparatus, wherein the substrate to be processed is transferred under control of a control apparatus 85 consecutively from the load-lock chamber 81A to the processing chamber 81, the processing chamber 82, the processing chamber 83 and the processing chamber 84, wherein the substrate finished with the processing in the processing chamber 84 is returned to the load-lock chamber 81B.

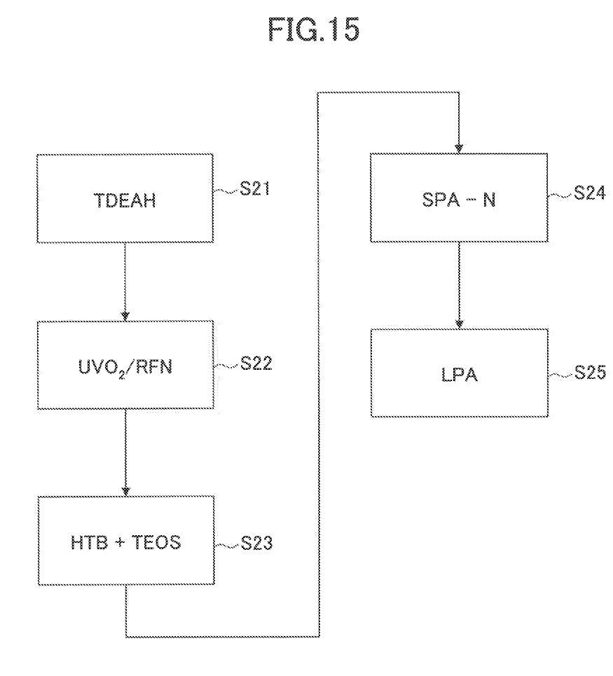

FIG. 15 is a flowchart showing the substrate processing carried out with the cluster-type substrate processing apparatus 80 of FIG. 14.

Referring to FIG. 15, the silicon substrate processed with the DHF treatment is forwarded to the processing chamber 81 from the load lock chamber 81A as the substrate to be processed (step 21), and the nucleation process of HfN by TDEAH explained previously in the step 2 of FIG. 13 is conducted at a substrate temperature of 400° C. With this, there is formed an HfN nucleation layer 22 on the surface of the silicon substrate.

Next, while the substrate to be processed is held in the processing chamber 81, the process of the step 2A of FIG. 12 is conducted (step 22), and there is formed an extremely thin silicon oxide film 22A or oxynitride film 22B explained with reference to FIG. 13 on the surface of the silicon substrate.

Next, the substrate thus processed is forwarded to the processing chamber 82 (step 23) and held at the temperature of 480° C. Further, the step 3 of FIG. 12 is conducted and there is formed an HfSiO₄ film 23 with a desired thickness such as 2-4 nm.

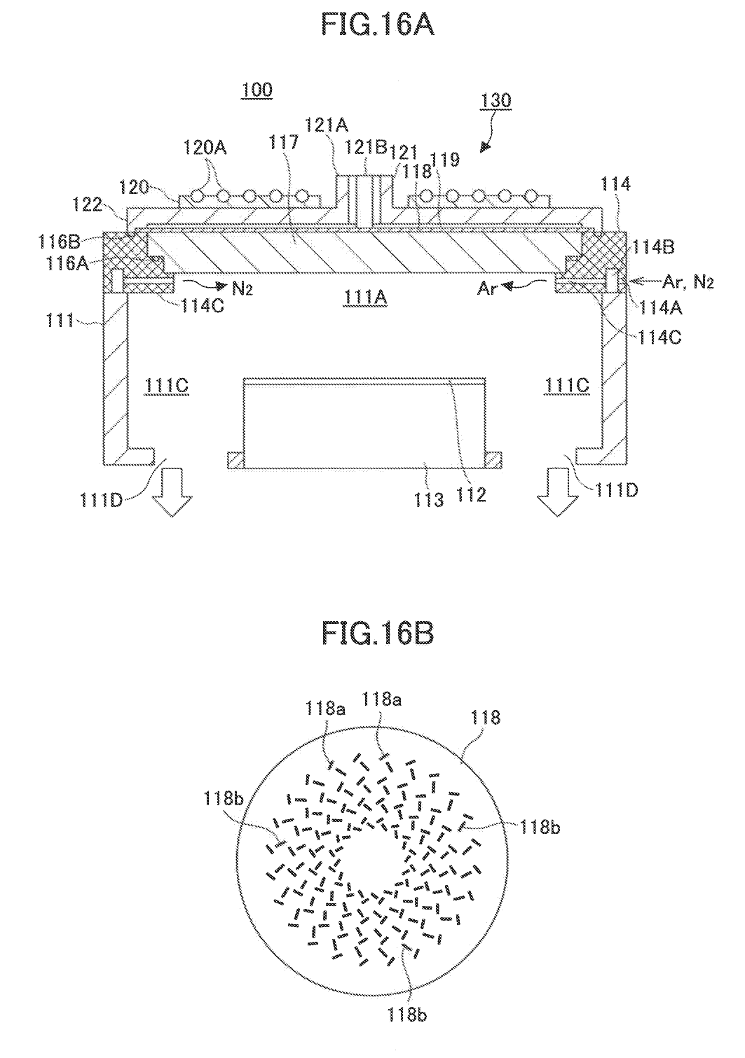

With the present embodiment, the silicon substrate thus formed with the HfSiO₄ film 23 is forwarded to a processing chamber 83 of a microwave plasma processing apparatus 100 of the construction shown in FIGS. 16A and 16B, for example (step 24), and the HfSiO₄ film is converted to an HfSiON film as a result of the nitridation processing.

Referring to FIG. 16A, the microwave plasma processing apparatus 100 includes a processing vessel 111 evacuated at a plurality of evacuation ports 111D and there is formed a stage 113 in the processing vessel 111 for holding the substrate 12 to be processed. In order to attain uniform evacuation of the processing vessel 111, there is formed a ring-shaped space 111C around the state 113, and the processing vessel 111 is evacuated uniformly via the space 111C and the evacuation ports 111D by forming the evacuation ports 111D in communication with the space 111C.

On the processing vessel 111, there is formed a ceramic cover plate 117 of a low-loss dielectric at a location corresponding to the substrate 12 on the stage 113 as a part of the outer wall of the processing vessel 111 via a seal ring 116A, such that the ceramic cover plate 117 faces the substrate 112 to be processed.

The cover plate 117 is seated upon a ring-shaped member 114 provided on the processing vessel 111 via the seal ring 116A, and ring member 114 is formed with a ring-shaped gas passage 114B in communication with a gas inlet port 114A and in correspondence to the ring-shaped member 114. Further, the ring-shaped member 114 is formed with a plurality of gas inlet openings 114C in communication with the gas supply passage 114B in axial symmetry with regard to the substrate 112 to be processed.

There, a gas such as Ar, Kr or Xe and H₂, or the like, supplied to the gas inlet port 114A is supplied to the inlet openings 114C from the gas passage 114B and is released from the inlet openings 114C to a space 111A in the processing vessel 111 right underneath the cover plate 117.

On the processing vessel 111, there is provided, over the cover plate 117, a radial line slot antenna 130 having a radiation surface shown in FIG. 16B with a distance of 4-5 mm from the cover plate 117.

The radial line slot antenna 130 is seated upon the ring-shaped member 114 via a seal ring 116B and is connected to an external microwave source (not illustrated) via a coaxial waveguide 121. The radial line slot antenna 130 induces excitation in the plasma gas related to the space 111A with the microwave from the microwave source.

The radial line slot antenna 130 comprises a flat disk-shaped antenna body 122 connected to an outer waveguide 121A of the coaxial waveguide 121 and a radiation plate 118 provided at the opening of the antenna body 122, wherein the radiation plate 118 is formed with a large number of slots 118a and a large number of slots 118b perpendicular to the slots 118a as shown in FIG. 16B. Further, there is inserted a delay plate 119 of a dielectric plate of a constant thickness between the antenna body 122 and the radiation plate 118. Further, the radiation plate 118 is connected to a central conductor 121B that constitutes a part of the coaxial waveguide 121. On the antenna body 122, there are provided cooling blocks 120 having a coolant passage 120A.

With the radial line slot antenna 130 of such a construction, the microwave fed from the coaxial waveguide 121 propagates between the disk-shaped antenna body 122 and the radiation plate 118 while spreading in the radial direction, wherein the microwave experiences wavelength compression during this process by the action of the delay plate 119. Thus, by forming the slots 118a and 118b in concentric patterns in correspondence to the wavelength of the microwave propagating in the radial direction in a mutually perpendicular relationship, it becomes possible to radiate a plane wave having circular polarization in the direction substantially perpendicular to the radiation plate 118.

By using such a radial line slot antenna 130, there is formed high-density plasma in the space 111A right underneath the cover plate 117 uniformly. It should be noted that the high-density plasma thus formed has low electron temperature and there is caused no damages in the substrate 12 to be processed. Further, there is caused no metal contamination originating from the sputtering of the vessel wall of the processing vessel 111.

Now, the silicon substrate 21 of the state 14 formed with the HfSiO₄ film 23 is held on the stage 113 in the processing vessel 83 at the temperature of 400° C., for example, as the substrate 12 to be processed, and the space 111 is supplied with a nitrogen gas together with an Ar gas. There, there are formed nitrogen radicals N* as a result of plasma excitation of nitrogen with Ar. The nitrogen radicals N* thus formed act upon the HfSiO₄ film on the silicon substrate 21 and substitutes a part of the oxygen atoms thereof. Thereby, the HfSiO₄ film is converted to an HfSiON film.

With the microwave plasma processing apparatus of FIGS. 16A and 16B, it should be noted that there is caused no penetration of electric charges into the HfSiO₄ film even when such plasma processing is conducted. This is because of the low electron temperature of plasma, which is only about several electron volts.

By using the HfSiO₄ film nitrided like this for the gate insulation film of a field effect transistor, penetration of dopant, particularly the penetration of B, into the channel region at the time of ion implantation process is blocked, and it becomes possible to stabilize the threshold characteristics of the field effect transistor. Further, as a result of such nitridation processing of HfSiO₄ film, there is caused increase of K value for the HfSiO₄ film, and it becomes possible to reduce the SiO₂ equivalent film thickness thereof.

Finally, the HfSiO₄ film thus obtained is annealed in the processing chamber 84 (step 25) and is further returned to the load lock chamber 81A or 81B.

It should be noted that the foregoing control of the cluster-type substrate processing apparatus 100 is performed by a controller 85.

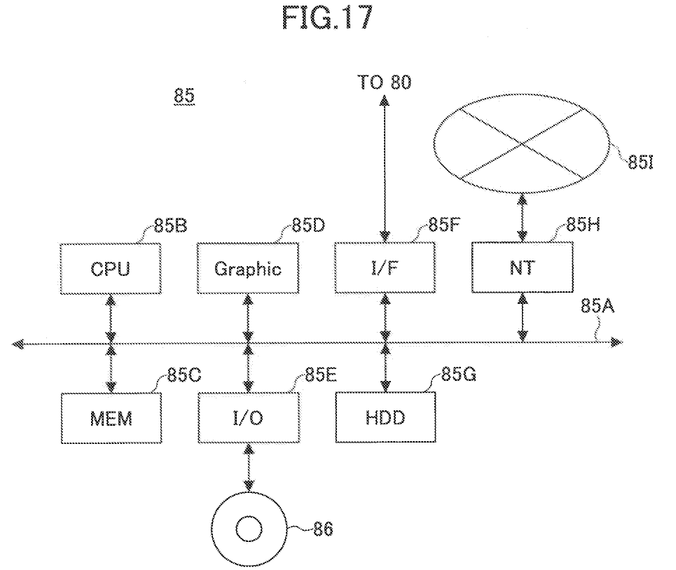

Typically, the controller 85 is formed of a general purpose computer of the construction shown in FIG. 17 and executes the foregoing control according to the control program code means recorded upon a computer-readable recording medium 86.

FIG. 17 shows a schematic construction of the controller 85.

Referring to FIG. 17, the controller 85 includes a system bus 85A, to which there are connected a CPU 85B, a memory unit 85C, a graphic card 85D, an input/output unit 85E, an interface card 85F, a hard disk unit 85G, a network controller 85H, or the like. There, the controller 85 controls the cluster type substrate processing apparatus 80 via the interface card 85F.

Particularly, the input/output unit 85 reads a magnetic recording medium or an optical recording medium recorded with a control program code under control of the CPU 85B and expands the control program over the memory unit 85C or the hard disk unit 85G. Further, the CPU executes the control program thus expanded consecutively and controls the substrate processing apparatus 80 via the interface card.

Further, it is also possible to download the control program from a network 85I via the network controller 85H.

While the present invention has been explained for preferred embodiments, the present invention is not limited to such specific embodiments and various variations and modifications may be made within the scope of the invention described in patent claims.

While the present invention has been explained for preferred embodiments, the present invention is not limited to such specific embodiments and various variations and modifications may be made within the scope of the invention described in patent claims.

What is claimed is:

1. A method for forming a high-K dielectric film on a silicon substrate, comprising the steps of:
processing a surface of said silicon substrate with a diluted hydrofluoric acid;
conducting nucleation process of HfN, after said step of processing with said diluted hydrofluoric acid, by supplying a metal organic source containing Hf and nitrogen to said surface of said silicon substrate; and
forming an Hf silicate film by a CVD process, after said step of nucleation, by supplying a metal organic source containing Hf and a metal organic source containing Si to said surface of said silicon substrate.

2. The method as claimed in claim 1, wherein said nucleation process of HfN is conducted at a temperature of 400° C. or less.

3. The method as claimed in claim 1, wherein said metal organic source containing Hf and nitrogen comprises an amide compound of hafnium.

4. The method as claimed in clam 1, wherein said nucleation process of HfN comprises a step of causing to flow tetrakis diethylamido hafnium along said surface of said silicon substrate as said metal organic source containing Hf and nitrogen.

5. The method as claimed in claim 1, further comprising, after said nucleation step of HfN but before said step of forming said Hf silicate film, the step of forming a silicon oxide film by oxidizing said surface of said silicon substrate by ultraviolet-excited oxygen radicals.

6. The method as claimed in claim 5, further comprising a step of nitriding at least a surface part of said silicon oxide film by plasma-excited nitrogen radicals.

7. The method as claimed in claim 1, wherein said step for forming said Hf silicate film by a CVD process is conducted by supplying tertiary butoxy hafnium and tetra ethoxy silane to said surface of said silicon substrate respectively as a metal organic source containing Hf and an organic source containing Si.

8. The film method as claimed in claim 1, wherein said CVD process is conducted at a temperature of 400° C. or higher.

9. The method as claimed in claim 1, further comprising, after said CVD process, the step of nitriding said dialectic film with plasma.

10. The method as claimed in claim 1, wherein said nucleation process is conducted in a first processing vessel and said CVD process is conducted in a second processing vessel different from said first processing vessel.

11. The method as claimed in claim 1, wherein said nucleation process and said CVD process are carried out in an identical processing vessel at respective substrate temperatures.

12. A computer-readable recording medium recorded with a program, the program causing a general purpose computer to control a substrate processing apparatus such that the substrate processing apparatus carries out a film formation process of a high-K dielectric film on a silicon substrate, the film formation process of the high-K dielectric film including the steps of:
processing a surface of the silicon substrate with a diluted hydrofluoric acid;
conducting nucleation process of HfN, after the step of processing with the diluted hydrofluoric acid, by supplying a metal organic source containing Hf and nitrogen to the surface of the silicon substrate; and
forming an Hf silicate film by a CVD process, after the step of nucleation, by supplying a metal organic source containing Hf and a metal organic source containing Si to the surface of the silicon substrate.

13. The computer-readable recording medium as claimed in claim 12, wherein said nucleation process of HfN is conducted at a temperature of 400° C. or less.

14. The computer-readable recording medium as claimed in claim 12, wherein said metal organic source containing Hf and nitrogen comprises an amide compound of hafnium.

15. The computer-readable recording medium as claimed in clam 12, wherein said nucleation process of HfN comprises a step of causing to flow tetrakis diethylamido hafnium along said surface of said silicon substrate as said metal organic source containing Hf and nitrogen.

16. The computer-readable recording medium as claimed in claim 12, further comprising, after said nucleation process of HfN but before said step of forming said Hf silicate film, the step of forming a silicon oxide film by oxidizing said surface of said silicon substrate by ultraviolet-excited oxygen radicals.

17. The computer-readable recording medium as claimed in claim 16, further comprising a step of nitriding at least a surface part of said silicon oxide film by plasma-excited nitrogen radicals.

18. The computer-readable recording medium as claimed in claim 12, wherein said CVD process for forming said Hf silicate film is conducted by supplying tertiary butoxy hafnium and tetra ethoxy silane to said surface of said silicon substrate respectively as a metal organic source containing Hf and an organic source containing Si.

19. The computer-readable recording medium as claimed in claim 12, wherein said CVD process is conducted at a temperature of 400° C. or higher.

20. The computer-readable recording medium as claimed in claim 12, further comprising, after said CVD process, the step of nitriding said high dialectic film with plasma.

21. The computer-readable recording medium as claimed in claim 12, wherein said nucleation process of conducted in a first processing vessel and said CVD process is conducted in a second processing vessel different from said first processing vessel.

22. The computer-readable recording medium as claimed in claim 12, wherein said nucleation process and said CVD process are carried out in an identical processing vessel at respective substrate temperatures.
